(19) United States
(12) Patent Application Publication
(10) Pub. No.: US 2006/0128072 A1
(43) Pub. Date: Jun. 15, 2006

(54) Method of protecting fuses in an integrated circuit die

(75) Inventors: Sarathy Rajagopalan, Milpitas, CA (US); Kishor Desai, Fremont, CA (US); Shirish Shah, San Ramon, CA (US)

Correspondence Address: LSI LOGIC CORPORATION, 1621 BARBER LANE, MS: D-106, MILPITAS, CA, 95035, US

(73) Assignee: LSI Logic Corporation

(21) Appl. No.: 11/011,459

(22) Filed: Dec. 13, 2004

(51) Int. Cl. H01L 21/82

(52) U.S. Cl. 438/131

(57) ABSTRACT

A fuse formed in an integrated circuit die includes: a length of an electrically conductive material for connecting two points of a circuit on the integrated circuit die and for selectively breaking the connection by a pulse of electrical current sufficient to dissolve a portion of the electrically conductive material; a passivation layer formed over the length of electrically conductive material; and a protective coating formed over a portion of the length of electrically conductive material in addition to the passivation layer to avoid damage to the fuse from an etchant during a bumping process.

### BACKGROUND OF THE INVENTION

1. Field of the Invention

The method of protecting fuses in an integrated circuit die from etching processes disclosed herein is directed to testing and screening of integrated circuit die. More specifically, but without limitation thereto, this method is directed to avoiding open circuits in fuses used in built-in self-repair schemes for integrated circuit dies.

2. Description of Related Art

In recently developed technologies for manufacturing integrated circuit dies in silicon wafers, built-in self-repair (BISR) schemes are used to map the address of a defective cell of, for example, a memory device, into a non-defective cell. After performing a self-diagnostic test routine to detect defective cells, the addresses of the defective cells are mapped to good cells by selectively opening fuses formed in the die. The fuses are selectively opened, or blown, by applying pulses of current that dissolve a portion of the fuse to break the electrical connection normally made by the fuse between two points of an electrical circuit in the die.

### SUMMARY OF THE INVENTION

In one embodiment, a method includes steps of:

(a) forming a fuse in an integrated circuit die that includes a passivation layer over the fuse; and

(b) coating a portion of the fuse with a protective coating in addition to the passivation layer to avoid damage to the fuse from an etching process.

In another embodiment, a fuse formed in an integrated circuit die includes:

a length of an electrically conductive material for connecting two points of an electrical circuit in the integrated circuit die and for selectively breaking the connection by a pulse of electrical current sufficient to dissolve a portion of the electrically conductive material;

a passivation layer formed over the length of electrically conductive material; and

a protective coating formed over a portion of the length of electrically conductive material in addition to the passivation layer to avoid damage to the fuse from an etchant during a bumping process.

### BRIEF DESCRIPTION OF THE DRAWINGS

The embodiments described herein are illustrated by way of example and not limitation in the accompanying figures, in which like references indicate similar elements throughout the several views of the drawings, and in which:

FIG. 1 illustrates a top view of a wafer street between two integrated circuit die according to the prior art;

FIG. 2 illustrates a top view of an array of built-in self-repair fuses formed in the die of FIG. 1 according to the prior art;

FIG. 3 illustrates an expanded side view of an end of one of the fuses in FIG. 2;

FIG. 4 illustrates an expanded top view of the end of the fuse in FIG. 3;

FIG. 5 illustrates an expanded side view of the end of the fuse in FIG. 3;

FIG. 6 illustrates a side view of a fuse coated at the ends to protect the fuse from etchant damage during a bumping process;

FIG. 7 illustrates a flow chart of a method of protecting a fuse in an integrated circuit die; and

FIG. 8 illustrates a top view of a fuse having only a standard passivation layer compared to an array of fuses coated according to FIG. 7.

Elements in the figures are illustrated for simplicity and clarity and have not necessarily been drawn to scale. For example, the dimensions of some elements in the figures may be exaggerated relative to other elements to point out distinctive features in the illustrated embodiments.

To simplify referencing in the description of the illustrated embodiments of the present invention, indicia in the figures may be used interchangeably to identify both the signals that are communicated between the elements and the connections that carry the signals. For example, an address communicated on an address bus may be referenced by the same number used to identify the address bus.

### DESCRIPTION OF THE ILLUSTRATED EMBODIMENTS

The fuses formed in integrated circuit die for a built-in self-repair scheme typically have a top metal layer made of aluminum.

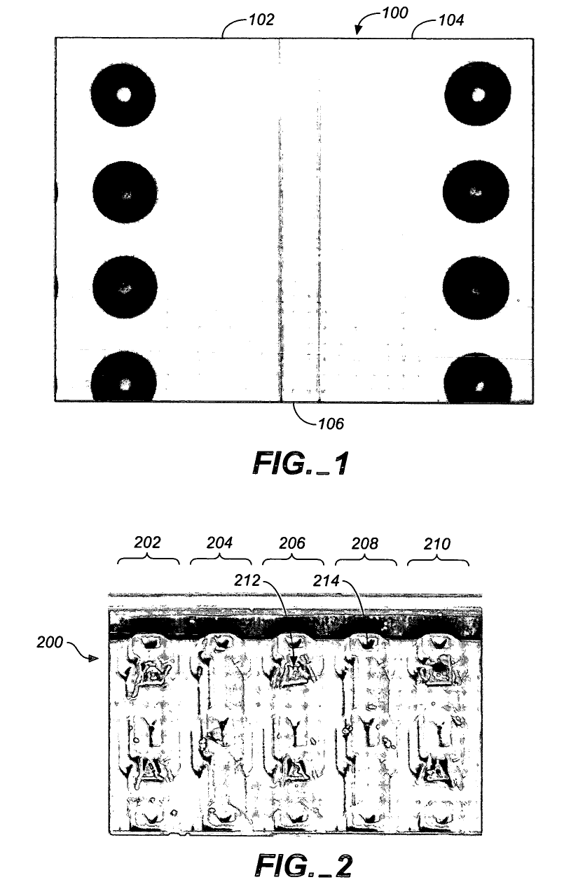

FIG. 1 illustrates a top view 100 of a wafer street between two integrated circuit die according to the prior art. Shown in FIG. 1 are portions 102 and 104 of two integrated circuit die and a saw street 106.

In FIG. 1, the saw street 106 separates the two portions 102 and 104 of two integrated circuit die so that neither of the die are damaged when the die are separated from one another by a dicing saw.

FIG. 2 illustrates a top view 200 of an array of built-in self-repair fuses formed in the integrated circuit die of FIG. 1 according to the prior art. Shown in FIG. 2 are fuses 202, 204, 206, 208 and 210, a space 212 left by a fuse section that has been blown by a current pulse, and a hole 214 in the passivation layer.

In FIG. 2, the fuses 204 and 208 are intact, that is, not opened by current pulses, while fuses 202, 206 and 208 are blown, that is, open-circuited by pulses of current. The space 212 was left by a fuse section that was blown by a current pulse. The hole 214 in the passivation layer of aluminum oxide in the center of the fuse end can allow the etchant used in a bumping process to attack the electrically conductive portion of the fuse as explained below.

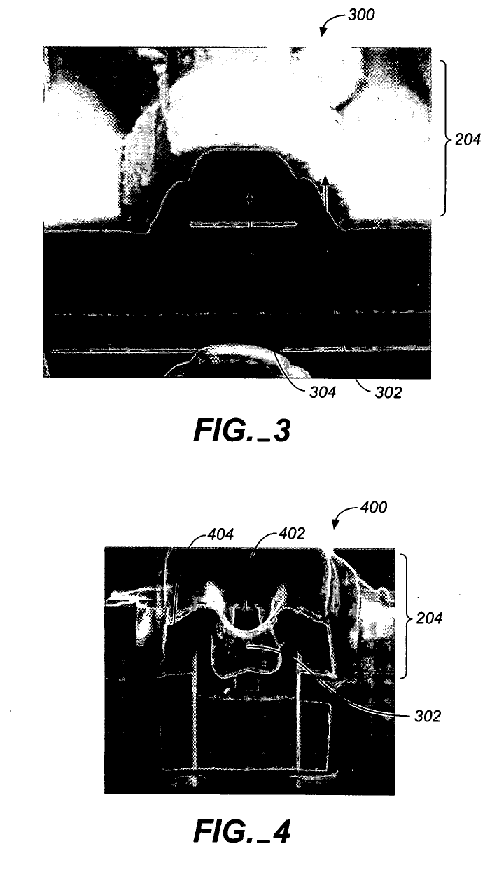

FIG. 3 illustrates an expanded side view 300 of an end of one of the fuses in FIG. 2. Shown in FIG. 3 are the end of the fuse 204, an aluminum oxide layer 302, and an aluminum electrical conductor 304.

In FIG. 3, the aluminum oxide layer 302 is a passivation layer that protects the aluminum electrical conductor 304 from etching used to form various semiconductor devices such as transistors on the die.

FIG. 4 illustrates an expanded top view 400 of the end portion of the fuse in FIG. 3. Shown in FIG. 4 are an end portion of the fuse 204, an aluminum oxide passivation layer 302, a passivation layer hole 402, and a void 404 under the passivation layer.

In FIG. 4, the center of the end portion of the fuse 204 has almost no aluminum oxide covering it, leaving the passivation layer hole 402. The etching processes for the under bump metallurgy (UBM) used to form solder bumps on an integrated circuit die typically use a strong solvent such as hydrofluoric acid that can etch away the aluminum oxide layer 302 at the passivation layer hole 402 and attack the aluminum electrical conductor below through the void 404 under the passivation layer. As a result, the aluminum electrical conductor may be etched away to such an extent that a fuse may be unintentionally opened, which could interfere with the address mapping performed by the built-in self-repair scheme.

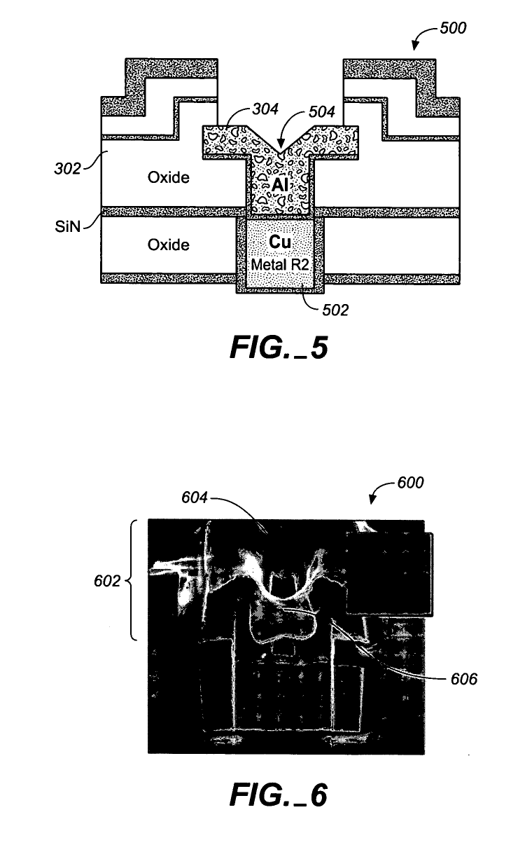

FIG. 5 illustrates an expanded side view 500 of the fuse in FIG. 3. Shown in FIG. 5 are an aluminum oxide layer 302, an aluminum electrical conductor 304, a via 502, and etchant damage 504.

In FIG. 5, the etching processes for the under bump metallurgy (UBM) used to form solder bumps can attack the aluminum electrical conductor 304, resulting in the etchant damage 504. The etchant damage 504 can break the electrical connection between the fuse and the via 502 below.

To solve the problem of unintentionally opening fuses during etching processes used to form solder bumps, improved etching materials may be found that react less aggressively with aluminum. Also, modifying the internal profile of the fuse to allow a conformal deposition of a passivation oxide without holes may mitigate the effect of etching the aluminum. Disadvantageously, these solutions require costly research to find a satisfactory etching material or impractical switching between high and low silicon processing temperatures to perform the passivation.

In a proposed method of protecting a fuse in an integrated circuit die, a coating is deposited on a portion of the fuse in addition to the passivation layer to prevent entry of an etching material that can enter the passivation layer during the bumping process and attack the aluminum electrical conductor of the fuse.

In one embodiment, a fuse formed in an integrated circuit die includes:

a length of an electrically conductive material for connecting two points of an electrical circuit in the integrated circuit die and for selectively breaking the connection by a pulse of electrical current sufficient to dissolve a portion of the electrically conductive material;

a passivation layer formed over the length of electrically conductive material; and

a protective coating formed over a portion of the length of electrically conductive material in addition to the passivation layer to avoid damage to the fuse from an etchant during a bumping process.

FIG. 6 illustrates a side view 600 of a fuse coated at the ends to protect the fuse from etchant damage during a bumping process. Shown in FIG. 6 are an end of a fuse 602, a protective coating 604, and an aluminum oxide passivation layer 606.

In FIG. 6, the protective coating 604 is applied, for example, to the ends of the fuse 602 in addition to the aluminum oxide passivation layer 606 prevent the strong etching solvent used in the bumping process from contacting the aluminum electrical conductor of the fuse and the resulting etchant damage.

In another embodiment, a method includes steps of:

(a) forming a fuse in an integrated circuit die that includes a passivation layer over the fuse; and

(b) coating a portion of the fuse with a protective coating in addition to the passivation layer to avoid damage to the fuse from an etchant during a bumping process.

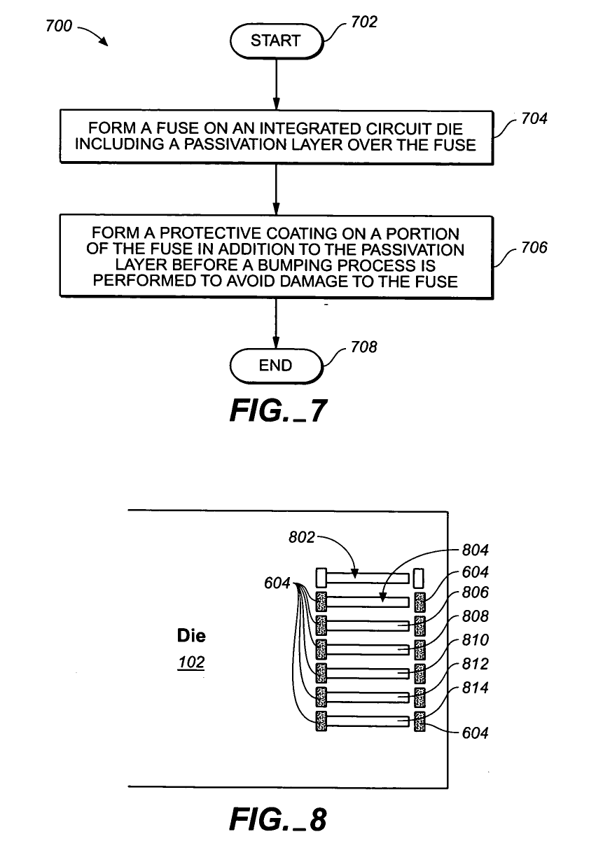

FIG. 7 illustrates a flow chart 700 of a method of protecting a fuse in an integrated circuit die.

Step 702 is the entry point of the flow chart 700.

In step 704, a fuse is formed on an integrated circuit die including a passivation layer over the fuse according to well known techniques.

In step 706, a protective coating is formed on a portion of the fuse in addition to the passivation layer before a bumping process is performed to avoid damage to the fuse from an etchant during the bumping process. By way of example, the protective coating may be polyimide or benzocyclobutene selectively spin coated on openings of the passivation layer over the fuse.

Step 708 is the exit point of the flow chart 710.

FIG. 8 illustrates a top view 800 of a fuse having only a standard passivation layer compared to an array of fuses coated according to the method of FIG. 7. Shown in FIG. 8 are fuses 802, 804, 806, 808, 810, 812 and 814.

In FIG. 8, the fuse 802 has only the standard passivation layer used in the prior art, while the fuses 804, 806, 808, 810, 812 and 814 are coated on the end corners shown by the shaded areas with the protective coating 604. As a result, the reliability of fuses 804, 806, 808, 810, 812 and 814 is enhanced over that of the fuse 802 because of the added protection provided by the protective coating 604 against damage from the strong solvent used during the bumping process. If desired, the protective coating 604 may be removed after the bumping process by a mild etchant that does not attack the aluminum conductor.

Although the flowchart description above is described and shown with reference to specific steps performed in a specific order, these steps may be combined, sub-divided, or reordered without departing from the scope of the claims. Unless specifically indicated herein, the order and grouping of steps is not a limitation of other embodiments that may lie within the scope of the claims.

The specific embodiments and applications thereof described above are for illustrative purposes only and do not preclude modifications and variations that may be made thereto by those skilled in the art within the scope of the following claims.

What is claimed is:

1. A method comprising steps of:
(a) forming a fuse in an integrated circuit die that includes a passivation layer over the fuse; and
(b) coating a portion of the fuse with a protective coating in addition to the passivation layer to avoid damage to the fuse from an etchant during a bumping process.

2. The method of claim 1 wherein step (b) comprises spin coating each end of the fuse with polyimide or benzocyclobutene.

3. The method of claim 1 wherein the protective coating comprises polyimide or BCB.

4. A fuse formed in an integrated circuit die comprising:
a length of an electrically conductive material for connecting two points of an electrical circuit in the integrated circuit die and for selectively breaking the connection by a pulse of electrical current sufficient to dissolve a portion of the electrically conductive material;
a passivation layer formed over the length of electrically conductive material; and
a protective coating formed over a portion of the length of electrically conductive material in addition to the passivation layer to avoid damage to the fuse from an etchant during a bumping process.

5. The fuse of claim 4 wherein the protective coating comprises a spin coating at each end of the fuse with polyimide or benzocyclobutene.

6. The fuse of claim 4 wherein the protective coating comprises polyimide or benzocyclobutene.
